(19) United States
(12) Patent Application Publication
(10) Pub. No.: US 2013/0234222 A1
(43) Pub. Date: Sep. 12, 2013

(54) SEMICONDUCTOR MEMORY DEVICE

(71) Applicants: Naoki YASUDA, Kanagawa-ken (JP); Masaaki Higuchi, Mie-ken (JP); Katsuyuki Sekine, Mie-ken (JP); Masao Shingu, Mie-ken (JP)

(72) Inventors: Naoki YASUDA, Kanagawa-ken (JP); Masaaki Higuchi, Mie-ken (JP); Katsuyuki Sekine, Mie-ken (JP); Masao Shingu, Mie-ken (JP)

(73) Assignee: Kabushiki Kaisha Toshiba, Tokyo (JP)

(21) Appl. No.: 13/598,748

(22) Filed: Aug. 30, 2012

(30) Foreign Application Priority Data
Mar. 8, 2012 (JP) 2012-052273

(51) Int. Cl. H01L 29/78

(52) U.S. Cl. 257/314; 257/E29.255

(57) ABSTRACT

A semiconductor memory device includes a substrate, a structure body, a semiconductor layer, and a memory film. The memory film is provided between the semiconductor layer and the plurality of electrode films. The memory film includes a charge storage film, a block film, and a tunnel film. The block film is provided between the charge storage film and the plurality of electrode films. The tunnel film is provided between the charge storage film and the semiconductor layer. The tunnel film includes a first film containing silicon oxide, a second film containing silicon oxide, and a third film provided between the first film and the second film and containing silicon oxynitride. When a composition of the silicon oxynitride contained in the third film is expressed by a ratio x of silicon oxide and a ratio (1−x) of silicon nitride, 0.5≦x<1 holdes.

### CROSS-REFERENCE TO RELATED APPLICATIONS

This application is based upon and claims the benefit of priority from the prior Japanese Patent Application No. 2012-052273, filed on Mar. 8, 2012; the entire contents of which are incorporated herein by reference.

### FIELD

Embodiments described herein relate generally to semiconductor memory device.

### BACKGROUND

These days, a three-dimensionally stacked semiconductor memory device is proposed in which multiple conductive films are collectively processed to increase the storage capacity of the memory. The semiconductor memory device includes a structure body including alternately stacked insulating films and electrode films, a semiconductor layer penetrating through the structure body, and a memory film between the semiconductor layer and the electrode films.

In such a semiconductor memory device, it is important to improve the retention of stored data and the data erase characteristics.

### BRIEF DESCRIPTION OF THE DRAWINGS

FIG. 1 is a schematic perspective view illustrating the configuration of a nonvolatile semiconductor memory device;

FIGS. 2A and 2B are schematic views illustrating a memory film;

FIG. 3 is a schematic enlarged cross-sectional view of the memory film;

FIG. 4 is a diagram showing relationships between the electric field and the hole current of the tunnel film;

FIG. 5 is a diagram showing the relationship between the ratio x and the erase threshold voltage;

FIG. 6 is a diagram showing erase characteristics in a circular cylindrical memory cell;

FIG. 7 is a diagram showing the relationship between the ratio x and the hole current amount;

FIG. 8 is a diagram showing relationships between the electric field and the electron current;

FIG. 9 is a diagram showing the relationship between the film thickness of the cap film and the attenuation factor of electron injection;

FIG. 10 is a diagram showing the relationship between the composition ratio x and the lower limit of the film thickness of the cap film;

FIG. 11 is a diagram showing the relationship between the film thickness of the cap film and the shift in the threshold voltage in data retention;

FIG. 12 is a diagram showing the relationship between the ratio x and the film thickness of the cap film; and

FIG. 13 is a schematic perspective view illustrating the configuration of a semiconductor memory device according to a second embodiment.

### DETAILED DESCRIPTION

According to one embodiment, a semiconductor memory device includes a substrate, a structure body, a semiconductor layer, and a memory film. The structure body is provided above a major surface of the substrate and includes a plurality of electrode films and a plurality of insulating films alternately stacked in a stacking direction perpendicular to the major surface. The semiconductor layer penetrates through the structure body in the stacking direction. The memory film is provided between the semiconductor layer and the plurality of electrode films. The memory film includes a charge storage film, a block film, and a tunnel film. The block film is provided between the charge storage film and the plurality of electrode films. The tunnel film is provided between the charge storage film and the semiconductor layer. The tunnel film includes a first film containing silicon oxide, a second film containing silicon oxide, and a third film provided between the first film and the second film and containing silicon oxynitride. When a composition of the silicon oxynitride contained in the third film is expressed by a ratio x of silicon oxide and a ratio (1−x) of silicon nitride, 0.5≦x<1 holdes.

Hereinbelow, embodiments of the invention are described based on the drawings.

The drawings are schematic or conceptual; and the relationships between the thickness and width of portions, the proportions of sizes among portions, etc. are not necessarily the same as the actual values thereof. Further, the dimensions and proportions may be illustrated differently among drawings, even for identical portions.

In the specification of this application and the drawings, components similar to those described in regard to a drawing thereinabove are marked with the same reference numerals, and a detailed description is omitted as appropriate.

### First Embodiment

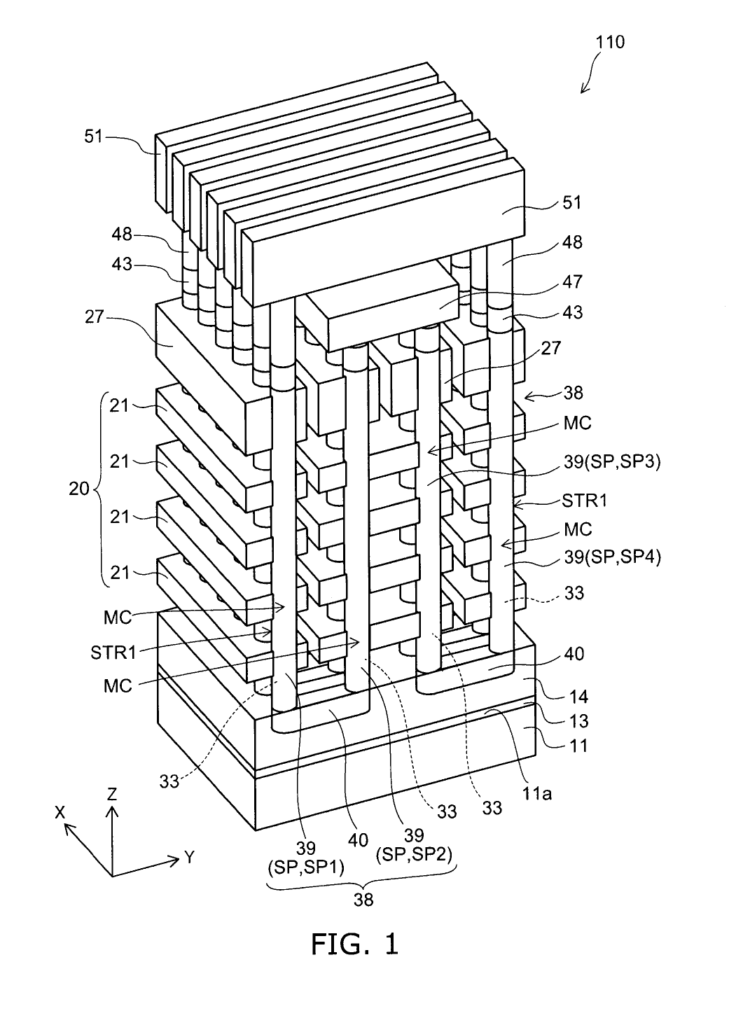

FIG. 1 is a schematic perspective view illustrating the configuration of a nonvolatile semiconductor memory device.

For easier viewing of the drawing, FIG. 1 shows only the conductive portions, and omits the insulating portions.

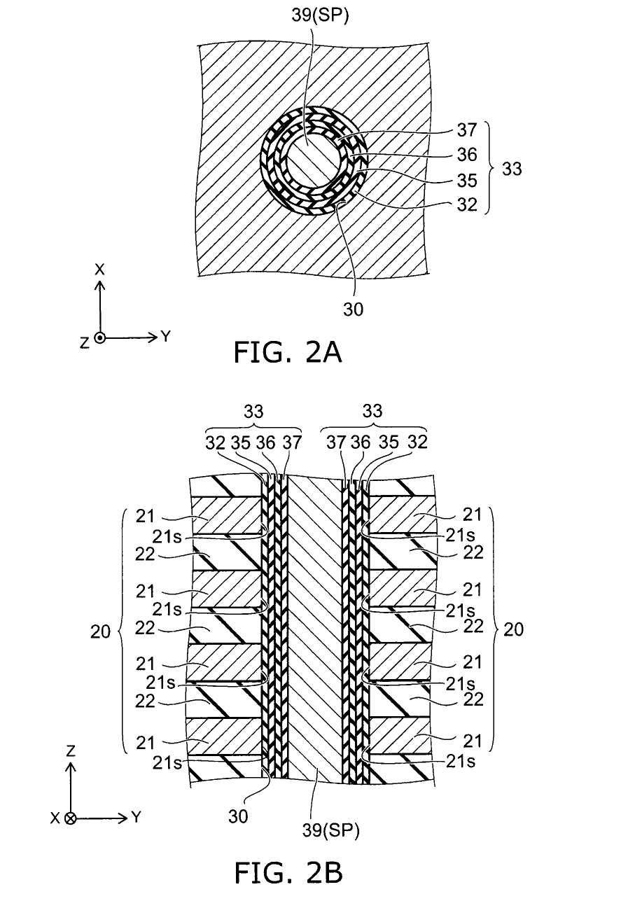

FIGS. 2A and 2B are schematic views illustrating a memory film.

FIG. 2A shows a schematic plan view of the memory film and an electrode film. FIG. 2B shows a schematic cross-sectional view of the memory film.

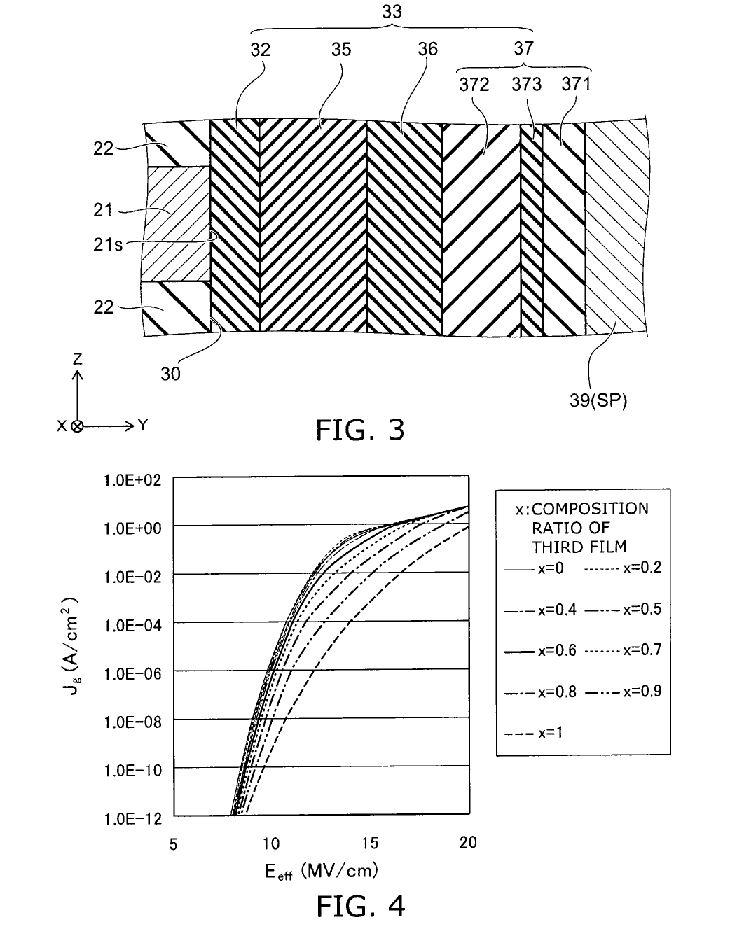

FIG. 3 is a schematic enlarged cross-sectional view of the memory film.

As shown in FIG. 1, a semiconductor memory device 110 includes a substrate 11, a structure body 20, semiconductor layers 39, and memory films 33.

In this specification, an axis orthogonal to the major surface 11a of the substrate 11 is defined as the Z-axis (a first axis), one of the axes (second axes) orthogonal to the Z-axis is defined as the X-axis, and an axis (third axis) that is another of the axes (second axes) orthogonal to the Z-axis and is perpendicular also to the X-axis is defined as the Y-axis.

The direction away from the major surface 11a of the substrate 11 along the Z-axis is referred to as upward (upper side), and the opposite direction is referred to as downward (lower side).

The structure body 20 is provided above the major surface 11a of the substrate 11. The structure body 20 includes a plurality of electrode films 21 and a plurality of insulating films 22 alternately stacked in the Z-axis direction (stacking direction). FIG. 1 shows a stacked body 20 in which four electrode films 21 are stacked. In the semiconductor memory device 110, the number of electrode films 21 stacked is not limited. The electrode film 21 is, for example, a word line.

The semiconductor layer 39 penetrates through the structure body 20 in the Z-axis direction. The semiconductor layer 39 is opposed to the side surfaces 21s (see FIG. 2B) of the plurality of electrode films 21. As an example of the semiconductor layer 39, a semiconductor pillar SP is used in the embodiment. The semiconductor pillar SP is, for example, a solid structure made of a semiconductor material. The semiconductor pillar SP may be a hollow structure made of a semiconductor material. The semiconductor pillar SP may be a structure including, for example, an insulating layer inside the hollow structure. In the embodiment, a plurality of semiconductor pillars SP are provided. The plurality of semiconductor pillars SP are provided in a matrix configuration along the X-axis and the Y-axis.

Of the plurality of semiconductor pillars SP, the semiconductor pillars SP in the same column aligned along the X-axis penetrate through the same electrode film 21. Of the four semiconductor pillars SP (a first semiconductor pillar SP1, a second semiconductor pillar SP2, a third semiconductor pillar SP3, and a fourth semiconductor pillar SP4) included in two U-shaped pillars 38 adjacent along the Y-axis, the inner two semiconductor pillars SP (the second semiconductor pillar SP2 and the third semiconductor pillar SP3) penetrate through the same electrode film 21. Of the four semiconductor pillars SP mentioned above, the outer two semiconductor pillars SP (the first semiconductor pillar SP1 and the fourth semiconductor pillar SP4) penetrate through the same electrode film 21. Each semiconductor pillar SP may be provided also so as to penetrate through a different electrode film 21.

As shown in FIG. 1 and FIGS. 2A and 2B, the memory film 33 is provided between the side surfaces 21s of the plurality of electrode films 21 and the semiconductor pillar SP. A memory cell transistor is formed by the memory film 33 provided in a position where the side surface 21s of the electrode film 21 and the semiconductor pillar SP intersect. Memory cell transistors are arranged in a three-dimensional matrix configuration, and each memory cell transistor functions as a memory cell MC that stores information (data) by storing a charge in a memory layer (a charge storage film 36).

Connection members 40 are provided between the substrate 11 and the structure body 20. The connection member 40 is connected to the ends of two semiconductor pillars SP adjacent along the Y-axis. The U-shaped pillar 38 includes two semiconductor pillars SP and the connection member 40 connecting them. A plurality of memory cells MC are arranged along the two semiconductor pillars SP included in the U-shaped pillar 38. One memory string STR1 includes one U-shaped pillar 38 and the plurality of memory cells MC provided in the U-shaped pillar 38. A plurality of memory strings STR1 are arranged in a matrix configuration above the substrate 11.

A conductive member 14 is provided between the substrate 11 and the connection member 40. The conductive member 14 is used as a back gate electrode BG. Silicon doped with phosphorus (phosphorus-doped silicon), for example, is used for the conductive member 14.

Control electrodes 27 are provided above the structure body 20 via a not-shown silicon oxide film. Boron-doped silicon, for example, is used for the control electrode 27. The control electrode 27 extends along the X-axis. The control electrode 27 is provided for each semiconductor pillar SP. The control electrode 27 is, for example, a select gate electrode SG.

A plug 43 is provided on the upper side of the control electrode 27. A source line 47 is connected, via plugs 43, to two adjacent semiconductor pillars SP (SP2 and SP3) out of the four semiconductor pillars SP (SP1, SP2, SP3, and SP4) included in two U-shaped pillars 38 adjacent along the Y-axis. A bit line 51 is connected to not-adjacent semiconductor pillars SP (SP1 and SP4) via plugs 43 and 48.

Next, the specific configuration of the memory film is described.

As shown in FIGS. 2A and 2B, the memory film 33 is provided in a memory hole 30 penetrating through the structure body 20 in the Z-axis direction. The memory hole 30 is provided in a circular shape as viewed in the Z-axis direction, for example. The memory film 33 is provided opposite to the plurality of electrode films 21 in the memory hole 30. The semiconductor pillar SP is provided in a central portion of the memory hole 30 to extend along the Z-axis direction. The memory film 33 is provided between the plurality of electrode films 21 and the semiconductor pillar SP in the memory hole 30.

The memory film 33 includes the charge storage film 36, a block film 35, a cap film 32, and a tunnel film 37.

The block film 35 is provided between the charge storage film 36 and the plurality of electrode films 21.

The cap film 32 is provided between the block film 35 and the plurality of electrode films 21.

The tunnel film 37 is provided between the charge storage film 36 and the semiconductor pillar SP.

That is, the memory film 33 has a configuration in which the cap film 32, the block film 35, the charge storage film 36, and the tunnel film 37 are provided in this order from the electrode film 21 toward the semiconductor pillar SP.

The memory film 33 is provided in a concentric circular configuration with center at the semiconductor pillar SP on the outside of the semiconductor pillar SP as viewed in the Z-axis direction. That is, as viewed in the Z-axis direction, the tunnel film 37 is provided so as to surround the outer periphery (circular outer periphery) of the semiconductor pillar SP, the charge storage film 36 is provided so as to surround the outer periphery of the tunnel film 37, the block film 35 is provided so as to surround the outer periphery of the charge storage film 36, and the cap film 32 is provided so as to surround the outer periphery of the block film 35. Thereby, the memory cell MC is configured in a circular cylindrical shape.

The cap film 32 has the function of suppressing erase saturation of the memory cell MC. The erase saturation refers to a phenomenon in which saturation occurs in the final stage of the erase operation of the memory cell MC. Silicon nitride, for example, is used for the cap film 32.

The block film 35 is a film that can substantially suppress leak current even when a voltage in the range of the drive voltage of the semiconductor memory device 110 is applied. For the block film 35, a high-dielectric material, for example, a material having a dielectric constant higher than the dielectric constant of the material forming the charge storage film 36 described later is used. In the case of the memory film 33 in a circular cylindrical shape, also a material having a lower dielectric constant than the material forming the charge storage film 36, such as silicon oxide, may be used for the block film 35.

The charge storage film 36 is a film that stores a charge. The charge storage film 36 is, for example, a film including trap sites for electrons. The charge storage film 36 contains silicon nitride, for example. The charge storage film 36 preferably contains silicon nitride or silicon oxynitride in its part.

As shown in FIG. 3, the tunnel film 37 includes a first film 371, a second film 372, and a third film 373. The first film 371 is a film containing silicon oxide. The second film 372 is a film containing silicon oxide. The third film 373 is a film containing silicon oxynitride.

The first film 371 is disposed on the semiconductor pillar SP side, and the second film 372 is disposed on the electrode film 21 side. The third film 373 is provided between the first film 371 and the second film 372. That is, the tunnel film 37 has a multiple-layer structure in which the first film 371, the third film 373, and the second film 372 are disposed in this order from the semiconductor pillar SP toward the electrode film 21.

As viewed in the Z-axis direction, the first film 371 is provided so as to surround the outer periphery of the semiconductor pillar SP, the third film 373 is provided so as to surround the outer periphery of the first film 371, and the second film 372 is provided so as to surround the outer periphery of the third film 373.

As the tunnel film 37, what is called an O (oxide film) N (nitride film) O (oxide film) structure of the first film 371 containing silicon oxide, the third film 373 containing silicon oxynitride, and the second film 372 containing silicon oxide may be used; thereby, the data retention characteristics of the memory cell MC are improved.

On the other hand, if the oxygen concentration in the third film 373 of the tunnel film 37 is high, the advantage of the erase characteristics of the memory cell MC is lost. Thus, in the case where the tunnel film 37 of an ONO structure is used for the memory cell MC, there is a trade-off between data erase characteristics and data retention characteristics depending on the composition of silicon oxynitride of the third film 373.

In the semiconductor memory device 110 according to the embodiment, the data retention and data erasability of the memory cell MC are attempted to be improved by the configuration of the third film 373 of the tunnel film 37. Specifically, when the composition of silicon oxynitride (SiON) contained in the third film 373 of the tunnel film 37 is expressed by the ratio x of silicon oxide (SiO₂) and the ratio (1−x) of silicon nitride (Si₃N₄), the semiconductor memory device 110 satisfies 0.5≦x<1. Thereby, the trade-off between data erase characteristics and data retention characteristics is relaxed.

When the composition of the charge storage film 36 containing silicon oxynitride is expressed by the ratio y of silicon oxide and the ratio (1−y) of silicon nitride, the semiconductor memory device 110 has the relationship of ratio y<ratio x. That is, when nitrogen is contained in the charge storage film 36, the density (volume density; /cm³ in number) of nitrogen of the charge storage film 36 is larger than the density (volume density; /cm³ in number) of nitrogen contained in the third film 373. This mainly corresponds to the occurrence of charge capture in the charge storage film 36.

The circular cylindrical memory cell MC has, due to its structure, the property that the electric field becomes weaker toward the outer periphery. Therefore, data write/erase operations in which leak current is suppressed are performed even without using a high-dielectric insulating film material (metal oxide) such as aluminum oxide for the block film 35. In the case where silicon oxide is used for the block film 35, if the film thickness of the cap film 32 is thickened, the electron injection from the electrode film 21 to the charge storage film 36 is suppressed and erase saturation is less likely to occur.

However, if the film thickness of the cap film 32 is thick, the amount of defects of the cap film 32 increases, and capture and release of charge are more likely to occur, causing degradation of the data retention characteristics of the memory cell MC. Thus, there is a trade-off between erase characteristics (erase saturation characteristics) and data retention characteristics depending on the film thickness of the cap film 32.

In the semiconductor memory device 110 according to the embodiment, the data retention and data erasability of the memory cell MC are attempted to be improved by the film thickness of the cap film 32. Specifically, the thickness of the cap film 32 is set to 8.5 nanometers (nm) or less. Furthermore, when 0.7≦x<1, the thickness of the cap film 32 is set to 13.7(x−0.7)^{1.6} nm or more. Thereby, the trade-off between data erase characteristics and data retention characteristics is relaxed.

The reason for reaching the conditions mentioned above regarding the composition of the third film 373 of the tunnel film 37 and the film thickness of the cap film 32 will now be described.

First, the relationship between the composition of the third film 373 of the tunnel film 37 and the film thickness of the cap film 32 is described.

When the composition of silicon oxynitride in the third film 373 of the tunnel film 37 is near silicon nitride (Si₃N₄), the hole current injected from the channel region (the semiconductor layer 39) into the tunnel film 37 in the erasing of data is large. In this case, erase saturation is less likely to occur even if the film thickness of the cap film 32 is thin, in other words, even if the electron injection from the electrode film 21 is large.

Conversely, when the composition of silicon oxynitride in the third film 373 of the tunnel film 37 is near silicon oxide (SiO₂), the hole current injected from the channel region into the tunnel film 37 in the erasing of data is small. In this case, erase saturation will occur unless the cap film 32 is made thick, in other words, unless the electron injection from the electrode film 21 is suppressed.

Thus, from the viewpoint of preventing erase saturation from occurring, the composition of silicon oxynitride in the third film 373 of the tunnel film 37 and the film thickness of the cap film 32 are related to each other. In the semiconductor memory device 110 according to the embodiment, this relationship is utilized.

Next, the optimum range of the composition of the third film 373 of the tunnel film 37 is described.

FIG. 4 is a diagram showing relationships between the electric field and the hole current of the tunnel film.

The tunnel film 37 includes films at both ends (the first film 371 and the second film 372) and a central film (the third film 373) provided between the films at both ends. The materials and the film thicknesses of the first film 371, the third film 373, and the second film 372 of the tunnel film 37 are as follows: the first film 371 (material: SiO₂, film thickness: 1.5 nm), the third film 373 (material: SiON, film thickness: 2 nm), and the second film 372 (material: SiO₂, film thickness: 2.5 nm).

The horizontal axis (E_{eff}) of FIG. 4 is the effective electric field of the applied electric field expressed on a SiO₂ basis (the value of the electric flux density divided by the dielectric constant of SiO₂). The vertical axis (J_{g}) of FIG. 4 represents the density of the hole current flowing through the tunnel film 37 mentioned above. The parameter x corresponding to each curve is the ratio x mentioned above of the third film 373 of the tunnel film 37. The composition of the third film 373 becomes nearer to a Si₃N₄ film as the value of the ratio x (0≦x≦1) decreases, and becomes nearer to SiO₂ as the ratio x increases.

As can be seen from the relationships shown in FIG. 4, in the tunnel film 37 of an ONO structure, the hole tunnel current density increases as the ratio x of the third film 373 is decreased. However, when the ratio x is less than 0.5, the current is rate-determined at the SiO₂ layers at both ends (the first film 371 and the second film 372) of the tunnel film 37, and a further tunnel current increase is not expected. This is because in the low electric field region, the two SiO₂ layers (the first film 371 and the second film 372) serve as the rate-determining step of the tunnel current, and in the high electric field region, the SiO₂ layer (the first film 371) in contact with the channel region determines the tunnel current.

Thus, if the ratio x of the third film 373 of the tunnel film 37 of an ONO structure is set to x<0.5, it is difficult to obtain a sufficient boosting effect from the viewpoint of erase characteristics. Furthermore, as described later, since decreasing the ratio x increases the amount of in-film defects of the third film 373, data retention characteristics become less good as the ratio x is decreased. From the above discussion, when both aspects of improving erase characteristics and maintaining data retention characteristics are considered, the ratio x of the tunnel film 37 of an ONO structure is at least within a range of 0.5≦x<1.

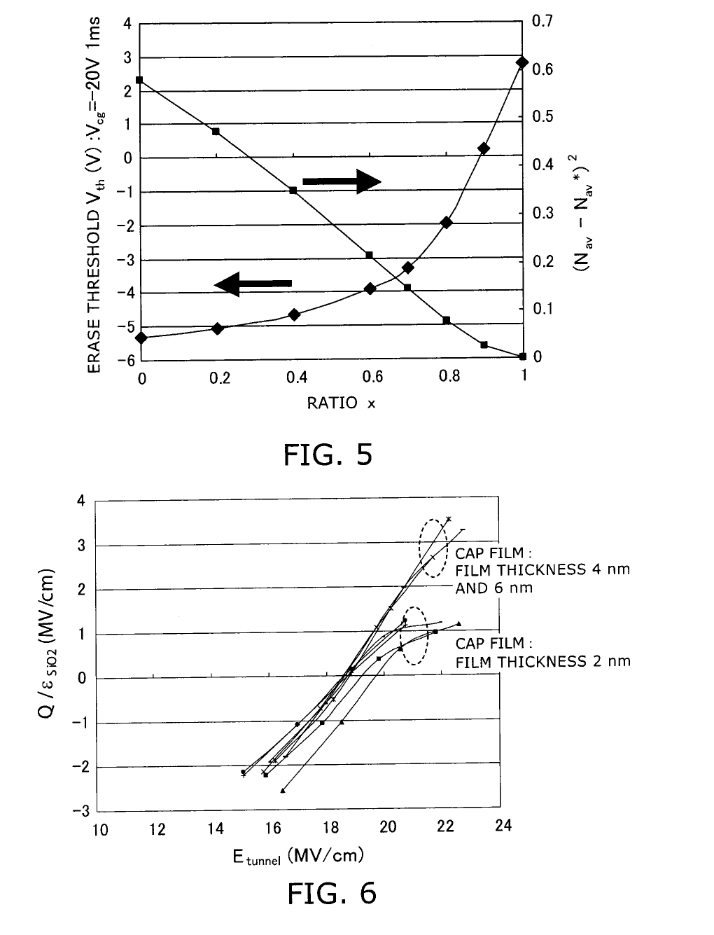

FIG. 5 is a diagram showing the relationship between the ratio x and the erase threshold voltage.

In FIG. 5, the vertical axis on the left side represents the erase threshold voltage level when a gate voltage Vcg=−20 volts (V) is applied to the electrode film 21 for one millisecond (ms) for the memory film 33 with the tunnel film 37 same as FIG. 4, the charge storage film 36 (material: Si₃N₄, film thickness: 5 nm), and the block film 35 (material: Al₂O₃, film thickness: 10 nm), and the horizontal axis represents the ratio x of the third film 373 of the tunnel film 37.

According to the results, it is found that the erase threshold level does not become so deep when the ratio x is less than 0.7. That is, when the erase threshold is denoted by Vₜₕ, |dVₜₕ/dx| becomes small with the ratio x=0.7 as a turning point, and the effect of erase performance improvement becomes not significant.

When considering along with the results shown in FIG. 4, even the region where the ratio x is less than 0.7 exhibits a certain level of improvement in erase characteristics. This is considered to be mainly because the EOT (equivalent oxide thickness) of SiON in the third film 373 of the tunnel film 37 becomes small and the electric field applied to the tunnel film 37 becomes large under the same gate voltage Vcg.

On the other hand, according to the reference document G. Lucovsky et al., “Bonding constraints and defect formation at interfaces between crystalline silicon and advanced single layer and composite gate dielectrics,” Appl. Phys. Lett. 74, 2005 (1999), the amount of in-film defects of a SiON film is proportional to (Nₐᵥ−Nₐᵥ*)² using the average coordination number Nₐᵥ where Nₐᵥ*=2.67. FIG. 5 shows a plot of (Nₐᵥ−Nₐᵥ*)² as a function of the ratio x of a SiON layer based on this theory (the vertical axis on the right side of FIG. 5 represents (Nₐᵥ−Nₐᵥ*)²).

According to the results, in a range of the ratio x of 1 to 0.7, since (Nₐᵥ−Nₐᵥ*)² behaves nearly quadratic, the defect density in the SiON film is kept low in the neighborhood of the ratio x=1. On the other hand, in a range of the ratio x of less than 0.7, (Nₐᵥ−Nₐᵥ*)² shows linear function-like behavior, and the defect density increases almost linearly as the ratio x decreases.

From this, it can be said that in a range of the ratio x of the third film 373 of the tunnel film 37 of not less than 0.7 and less than 1, the in-film defect density is suppressed and the effect of erase characteristic improvement appears significantly as well as data retention. Note that when the ratio x=0.7, Nₐᵥ is equal to 3.04.

According to the reference document mentioned above (G. Lucovsky), it is experimentally known that Nₐᵥ˜3 is a criterion for distinguishing between the cases of the defect density being small and large. The boundary value by which the composition of the third film 373 is equal to the ratio x=0.7 or more in the tunnel film 37 of an ONO structure in the embodiment almost agrees with the criteria for the largeness and smallness of the amount of in-film defects in the reference document mentioned above (G. Lucovsky). Therefore, to achieve improvement in the data retention characteristics and data erase characteristics of the memory cell MC, the ratio x of the third film 373 of the tunnel film 37 is preferably set to a value in a range of 0.7≦x<1.

Next, the optimum range of the film thickness of the cap film 32 is described.

First, the lower limit of the film thickness of the cap film 32 is described.

The lower limit of the film thickness range of the cap film 32 is obtained by the conditions under which, in the final stage of the erase operation, the hole current flowing from the channel region to the charge storage film 36 via the tunnel film 37 is balanced with the electron current flowing from the electrode film 21 to the charge storage film 36 via the cap film 32.

FIG. 6 is a diagram showing erase characteristics in a circular cylindrical memory cell.

FIG. 6 shows the results of measuring erase characteristics (erase time: 10 ms) using a plurality of samples in which the film thicknesses and formation conditions of the films (the tunnel film 37, the charge storage film 36, and the block film 35) are changed. All of the tunnel films 37 of the memory cells MC of the plurality of samples are a single-layer film of SiO₂.

The horizontal axis of FIG. 6 represents the electric field Eₜᵤₙₙₑₗ (MV/cm) of the tunnel film 37 in a state where there is no charge trapping. That is, the electric field corresponds to the gate voltage applied in the erase operation. The vertical axis of the drawing represents the amount of charge Q (MV/cm) building up in the charge storage film 36 at the end of the erase operation.

Q<0 indicates the state where a negative charge builds up in the charge storage film 36, and Q>0 indicates the state where a positive charge builds up in the charge storage film 36. In the erase operation of the circular cylindrical memory cell MC, it is required to start the erase operation from a state on the Q<0 side and reach at least the neutral state of Q=0.

As shown in FIG. 6, in the case where the tunnel film 37 is a single-layer film of SiO₂, when the film thickness of the cap film 32 is set to approximately 2 nm, the neutral state of Q=0 is reached. In this case, erase saturation may occur immediately after entering the region of Q>0. When the film thickness of the cap film 32 is set to 4 nm or 6 nm, erase saturation does not occur even upon entering the state of Q>0 in the measurement range.

From the above, it is found that in the circular cylindrical memory cell MC, the lower limit of the film thickness of the cap film 32 may be set to 2 nm when the tunnel film is a single-layer film of SiO₂. Since this is determined by the electric field, even when the memory hole diameter of the circular cylindrical memory cell MC is reduced, the same conclusion is obtained under the conditions where the film thicknesses of the films (the tunnel film 37, the charge storage film 36, and the block film 35) and the applied voltage are proportionally reduced.

In view of the lower limit value (2 nm) of the film thickness of the cap film 32 when the tunnel film 37 is a single-layer film of SiO₂ described above, next, a description is provided on how the lower limit of the film thickness of the cap film 32 is when the tunnel film 37 has an ONO structure. Herein, it is necessary to investigate (1) how the hole injection current at the end of erasing changes in accordance with the composition of the third film 373 of the tunnel film 37, and (2) how the film thickness of the cap film 32 when electron injection in an equal amount to the hole injection current occurs is. Then, based on the results, the relationship between the composition of the third film 373 of the tunnel film 37 and the lower limit of the film thickness of the cap film 32 is determined.

First, (1) mentioned above is described. It is considered that in qualitative terms, as the hole injection current increases by the composition of SiON of the third film 373 becoming nearer to Si₃N₄, the time until the erase operation up to a prescribed threshold level decreases and the amount of hole current at the end of erasing increases. The actual magnitude of the hole current has been investigated based on the erase characteristics of the memory cell MC including the memory film 33 same as FIG. 5. The erase operation down to near the neutral threshold (approximately 0.4 V) was performed using this memory cell MC to investigate the magnitude of the hole current at the end of erasing.

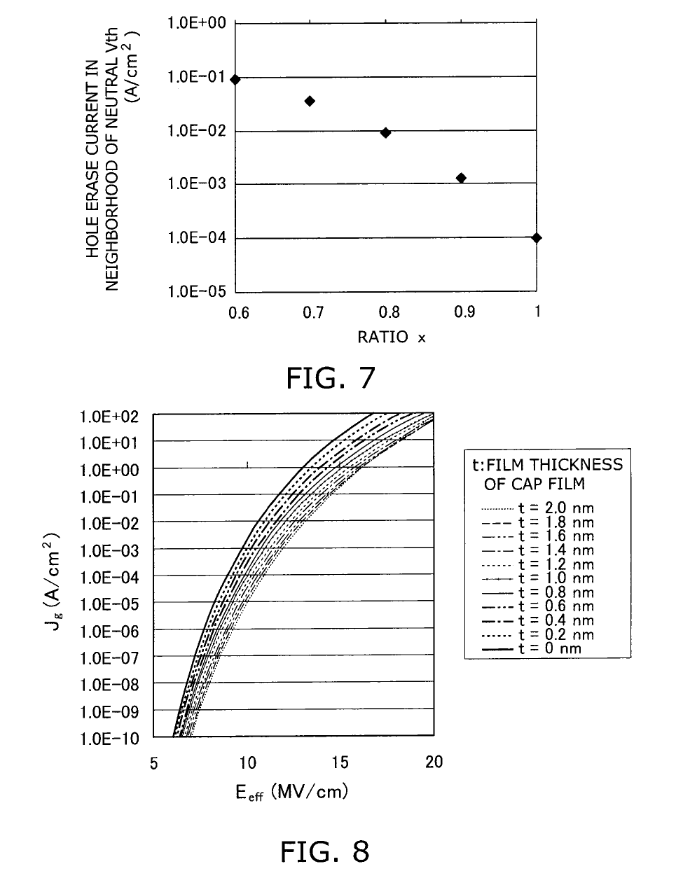

FIG. 7 is a diagram showing the relationship between the ratio x and the hole current amount.

FIG. 7 shows the erase characteristics of the memory cell MC including the memory film 33 same as FIG. 5. The horizontal axis of FIG. 7 represents the ratio x of the third film 373 of the tunnel film 37 of an ONO structure, and the vertical axis represents the amount of hole current (A/cm²) flowing in the neighborhood of the neutral threshold condition. As can be seen from FIG. 7, as the ratio x of the composition of the third film 373 becomes nearer to SiO₂, since erasing becomes slower, the hole current at the end of erasing becomes smaller. That is, by changing the ratio x of the third film 373 from 0.6 to 1, the hole current becomes one thousandth. Although the absolute value of the hole current at the end of erasing changes with the film thickness of the first film 371 in contact with the channel region of the tunnel film 37 of an ONO structure, it is considered that the rate of the increase and decrease of the hole current due to the composition change of the third film 373 has little dependence on the film thickness of the first film 371.

Next, an investigation has been made on how the amount of electrons injected from the electrode film 21 into the charge storage film 36 decreases due to an increase in the film thickness of the cap film 32.

FIG. 8 is a diagram showing relationships between the electric field and the electron current.

FIG. 8 shows the electric field (E_{eff} (MV/cm))-current (J_{g} (A/cm²)) characteristics when electron injection is performed from the cap film side in a stacked film of a thick block SiO₂ film (thickness: 10 nm or more) and a cap Si₃N₄ film in contact with it.

The case of the thickness of the cap film being zero corresponds to the electric field-current characteristics of SiO₂, and lower currents than that are obtained in the cases of thicker film thicknesses of the cap film. Based on these characteristics, the relationship between the cap film thickness and the attenuation factor of the gate-injected electron amount is obtained. Although the attenuation factor slightly varies with the electric field at which it is investigated, the attenuation factor may be investigated at a relatively low electric field in view of the fact that in the circular cylindrical memory cell MC, the electric field decreases toward the outer periphery of the circular cylinder.

Herein, the attenuation factor of the injected electron current in an electric field of 8 MV/cm has been investigated.

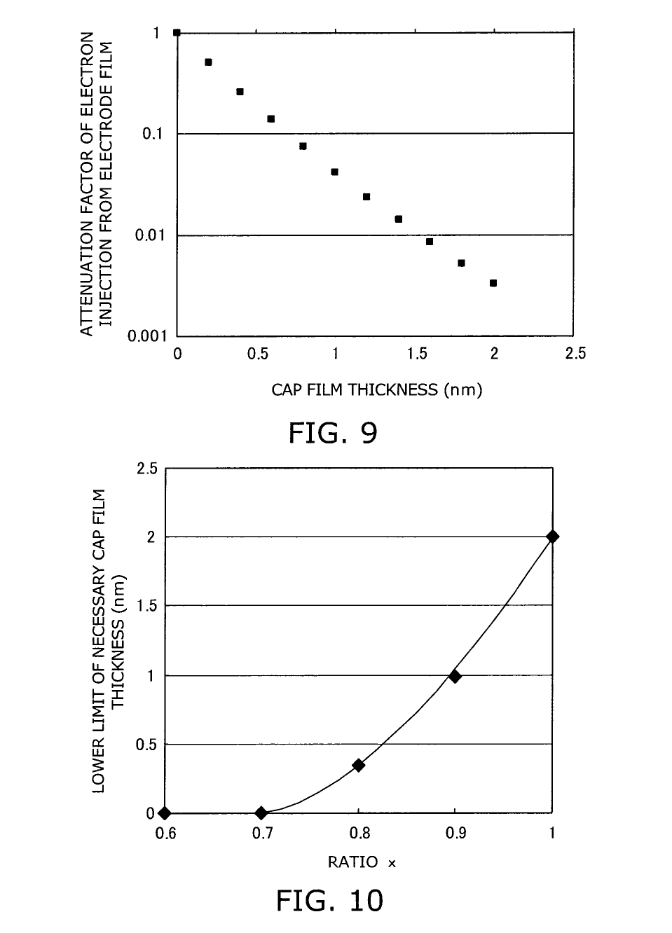

FIG. 9 is a diagram showing the relationship between the film thickness of the cap film and the attenuation factor of electron injection.

The horizontal axis of FIG. 9 represents the film thickness (nm) of the cap film, and the vertical axis represents the attenuation factor of the electron injection from the electrode film. The vertical axis shows relative values using the case of the film thickness of the cap film being zero as a reference.

As shown in FIG. 9, the attenuation factor of the electron current by the cap film of 2 nm in thickness is 0.003, and it is found that as the film thickness of the cap film is made thinner, the value of the attenuation factor becomes larger and the suppression of the electron current becomes less effective.

From the above, the minimum conditions for preventing erase saturation from occurring are found by the following procedure. First, the case where the ratio x of the third film 373 of the tunnel film 37=1 and the cap film thickness is 2 nm is taken as a reference. Next, the cap film 32 is made thinner into a thin film by an amount equivalent to the increase of the hole current due to the composition change (x<1) of the third film 373 of the tunnel film 37, thereby relaxing the suppression (attenuation factor) of the electron current.

FIG. 10 is a diagram showing the relationship between the composition ratio x of the third film 373 of the tunnel film 37 and the lower limit of the film thickness of the cap film.

The horizontal axis of FIG. 10 represents the ratio x, and the vertical axis represents the lower limit of the necessary film thickness (nm) of the cap film.

As shown in FIG. 10, it is found that the cap film 32, which required 2 nm in the case of the ratio x of the composition of the third film 373 of the tunnel film 37=1 (i.e., a SiO₂ film), may be made thinner with a decrease in the ratio x. It is found that at x=0.7, even setting the film thickness of the cap film 32 to zero does not cause erase saturation at least in the erase operation down to near the neutral threshold voltage.

That is, the lower limit of the film thickness of the cap film 32 is expressed as follows in accordance with the ratio x of the composition of the third film 373 of the tunnel film 37.

When 0≦x<0.7, the lower limit of the film thickness of the cap film 32 is 0 nm.

When 0.7≦x<1, the lower limit of the film thickness of the cap film 32 is 13.7(x−0.7)^{1.6} nm.

Next, the upper limit of the film thickness of the cap film 32 is described.

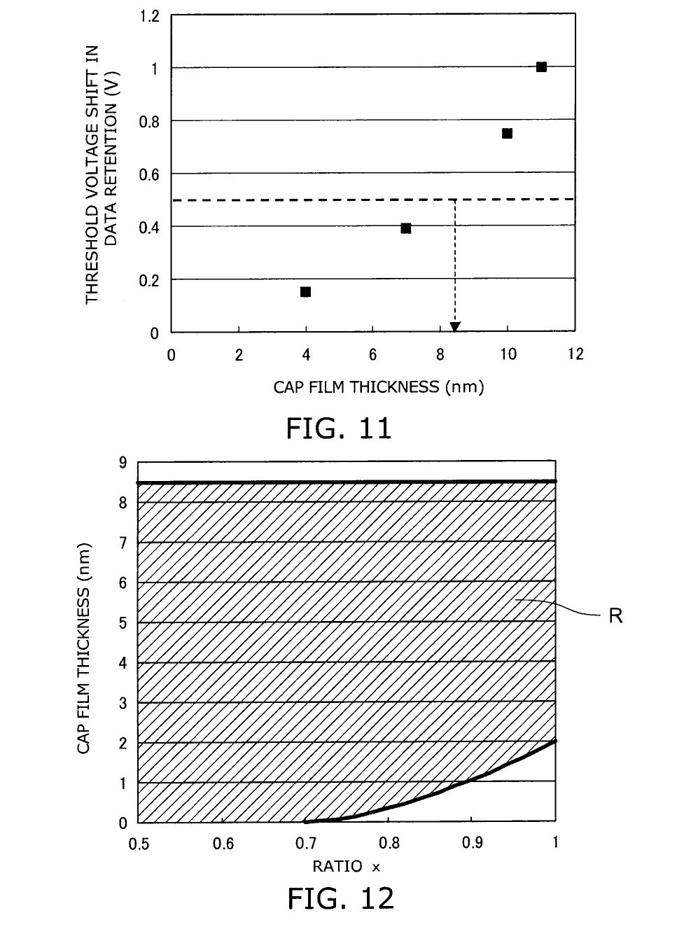

FIG. 11 is a diagram showing the relationship between the film thickness of the cap film and the shift in the threshold voltage in data retention.

The horizontal axis of FIG. 11 represents the film thickness (nm) of the cap film 32, and the vertical axis represents the shift in the threshold voltage (V) in data retention.

Here, the drawing shows the actual measurement results of data retention characteristics when the film thickness of the cap film 32 was changed in the circular cylindrical memory cell MC (after writing with a fresh sample, the temperature was kept at 85° C.). As shown in FIG. 11, as the film thickness of the cap film 32 increases, the threshold voltage shift in data retention increases in proportion to almost the square of the film thickness of the cap film 32. This indicates that captured electrons exist at a uniform density in the entire cap film 32. In view of the threshold voltage budget in multiple-value operations of the memory cell MC, it is necessary to suppress the shift of the threshold voltage in data retention to at least approximately 0.5 V or less.

From this, the upper limit of the film thickness of the cap film 32 is approximately 8.5 nm.

FIG. 12 is a diagram showing the relationship between the ratio x and the film thickness of the cap film.

The horizontal axis of FIG. 12 represents the ratio x, and the vertical axis represents the film thickness (nm) of the cap film.

As shown in FIG. 12, region R (the region indicated by hatching) indicates a region where the film thickness of the cap film 32 is not less than 0 nm and not more than 8.5 nm in the case of 0.5≦x<0.7 and the film thickness of the cap film 32 is not less than 13.7(x−0.7)^{1.6} nm and not more than 8.5 nm in the case of 0.7≦x<1.

If the ratio x and the film thickness of the cap film 32 are in region R, both improvement in data retention and improvement in data erase characteristics are achieved.

### Second Embodiment

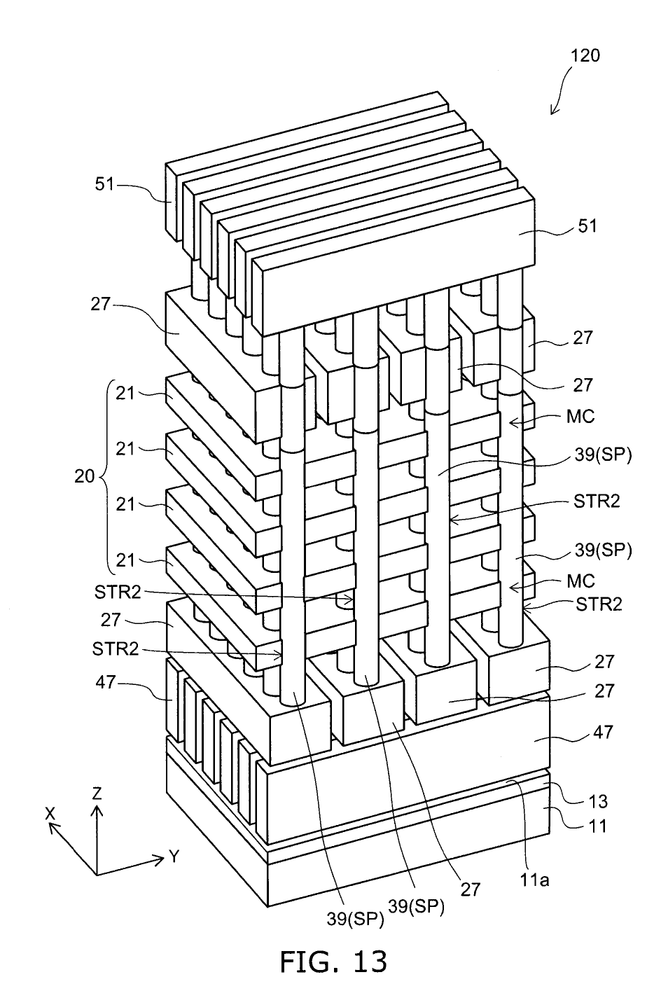

FIG. 13 is a schematic perspective view illustrating the configuration of a semiconductor memory device according to a second embodiment.

For easier viewing of the drawing, FIG. 13 shows only the conductive portions and omits the insulating portions.

As shown in FIG. 13, a semiconductor memory device 120 according to the second embodiment does not include the connection member 40 of the semiconductor memory device 110 shown in FIG. 1. That is, each of the semiconductor layers 39 (the semiconductor pillars SP) is independent. In the semiconductor memory device 120, rectilinear memory strings STR2 are provided.

In the semiconductor memory device 120, the control electrode 27 is provided individually on the upper side and the lower side of the structure body 20. The control electrode 27 is provided for each of the plurality of semiconductor pillars SP aligned along the X-axis. The plurality of source lines 47 are provided between the control electrode 27 on the lower side and the substrate 11, and each extends along the Y-axis. The plurality of bit lines 51 are provided above the control electrode 27 on the upper side, and each extends along the Y-axis.

Similar configurations of the memory film 33 to the semiconductor memory device 110 described above may be applied to the semiconductor memory device 120. Thereby, improvement in the retention of stored data and data erase characteristics are achieved.

Next, examples are described.

### First Example

A semiconductor memory device according to a first example has the following configuration.

The memory hole 30 has a hole diameter of 70 nm. The first film 371 of the tunnel film 37 is made of SiO₂, and has a film thickness of 1.5 nm. The third film 373 is made of SiON, has a ratio x of 0.75, and has a film thickness of 2 nm. The second film 372 is made of SiO₂, and has a film thickness of 2.5 nm. The charge storage film 36 is made of Si₃N₄, and has a film thickness of 5 nm. The block film 35 is made of SiO₂, and has a film thickness of 10 nm. The cap film 32 is made of Si₃N₄, and has a film thickness of 3 nm.

In the semiconductor memory device according to the first example thus configured, by setting the ratio x of the composition of the third film 373 of the tunnel film 37 to 0.75, an average coordination number Nₐᵥ of this layer=3 is obtained. Thereby, the in-film defect density of the third film 373 is reduced. The semiconductor memory device according to the first example achieves both good data retention characteristics and quick erase characteristics. The semiconductor memory device according to the first example is suitable for multiple-value operations.

### Second Example

A semiconductor memory device according to a second example has the following configuration.

The memory hole 30 has a hole diameter of 70 nm. The first film 371 of the tunnel film 37 is made of SiO₂, and has a film thickness of 1.5 nm. The third film 373 is made of SiON, has a ratio x of 0.6, and has a film thickness of 2 nm. The second film 372 is made of SiO₂, and has a film thickness of 2.5 nm. The charge storage film 36 is made of Si₃N₄, and has a film thickness of 5 nm. The block film 35 is made of SiO₂, and has a film thickness of 10 nm. The cap film 32 is made of Si₃N₄, and has a film thickness of 1 nm. The film thickness of the cap film 32 may be zero (the cap film 32 may not be provided).

In the semiconductor memory device according to the second example thus configured, by setting the ratio x of the composition of the third film 373 of the tunnel film 37 to 0.6, quick erase operation is provided. The semiconductor memory device according to the second example is suitable for uses in which the write/erase operations are quickly performed.

### Third Example

A semiconductor memory device according to a third example has the following configuration.

The memory hole 30 has a hole diameter of 56 nm. The first film 371 of the tunnel film 37 is made of SiO₂, and has a film thickness of 1 nm. The third film 373 is made of SiON, has a ratio x of 0.9, and has a film thickness of 1.5 nm. The second film 372 is made of SiO₂, and has a film thickness of 2 nm. The charge storage film 36 is made of Si₃N₄, and has a film thickness of 3 nm. The block film 35 is made of SiO₂, and has a film thickness of 8 nm. The cap film 32 is made of Si₃N₄, and has a film thickness of 2 nm.

In the semiconductor memory device according to the third example thus configured, the hole diameter of the memory hole 30 is small as compared to the first and second examples. By the hole diameter of the memory hole 30 being small, the effect of the circular cylindrical shape works. Consequently, sufficient erase characteristics are obtained even if the third film 373 of the tunnel film 37 has a composition near SiO₂. In the third example, the ratio x of the composition of the third film 373 of the tunnel film 37=0.9, and the composition is relatively on the SiO₂ side as compared to the first and second examples. The ratio x may be not less than 0.8 and not more than 0.95. In the semiconductor memory device according to the third example, the film thicknesses of the insulating films are generally set thin. By these film thicknesses and composition configurations, the write/erase operations can be provided with a sufficient margin, while importance is attached to data retention characteristics. Since the semiconductor memory device according to the third embodiment has a small hole diameter of the memory hole as compared to the semiconductor memory devices according to the first and second examples, the semiconductor memory device allows design for increasing device density and is suitable for semiconductor memory devices of high bit density.

As described above, the semiconductor memory device according to the embodiment can improve the retention of stored data and data erasability.

The embodiments are described in the above, but the invention is not limited to these examples. For example, the composition of the Si₃N₄ film of the charge storage film 36 may not be the stoichiometric composition, but be a Si-rich silicon nitride film or a N-rich silicon nitride film. Furthermore, the charge storage film 36 may be a stacked structure of a Si₃N₄ film and a high-dielectric (high-k) insulating film having a higher dielectric constant than SiO₂, such as HfO₂ and Al₂O₃. Furthermore, the charge storage film 36 may be a single-layer film of a high-k insulating film or a stacked film of different high-k insulating films. Moreover, various modifications may be applied to the configuration of the charge storage film 36.

Although SiO₂ is used as the material of the block film 35 in the embodiments and the examples described above, what is called an ONO film of SiO₂/SiON/SiO₂ may be used instead. Moreover, various modifications may be applied to the configuration of the block film 35.

In addition, the cap film 32 may contain impurity elements that are unintentionally mixed in, such as oxygen, hydrogen, and chlorine, at the interface of the cap film 32 with an adjacent film or in the interior of the cap film 32. Similarly, also other films may contain impurity elements that are unintentionally mixed in.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the invention.

What is claimed is:

1. A semiconductor memory device comprising:
a substrate;
a structure body provided above a major surface of the substrate and including a plurality of electrode films and a plurality of insulating films alternately stacked in a stacking direction perpendicular to the major surface;
a semiconductor layer penetrating through the structure body in the stacking direction; and
a memory film provided between the semiconductor layer and the plurality of electrode films,
the memory film including:
a charge storage film;
a block film provided between the charge storage film and the plurality of electrode films; and
a tunnel film provided between the charge storage film and the semiconductor layer,
the tunnel film including a first film containing silicon oxide, a second film containing silicon oxide, and a third film provided between the first film and the second film and containing silicon oxynitride,
when a composition of the silicon oxynitride contained in the third film is expressed by a ratio x of silicon oxide and a ratio (1−x) of silicon nitride, 0.5≦x<1 being satisfied.

2. The device according to claim 1, wherein
0.5≦x<0.7 is satisfied, and
the block film directly contacts on the plurality of electrode films.

3. The device according to claim 1, further comprising a cap film provided between the block film and the plurality of electrode films,
0.5≦x<0.7 being satisfied, and
a film thickness of the cap film being 8.5 nanometers or less.

4. The device according to claim 1, further comprising a cap film provided between the block film and the plurality of electrode films,
0.7≦x<1 being satisfied, and
a thickness of the cap film is not less than 13.7(x−0.7)^{1.6} nanometers and not more than 8.5 nanometers.

5. The device according to claim 3, wherein the cap film contains silicon nitride.

6. The device according to claim 4, wherein the cap film contains silicon nitride.

7. The device according to claim 1, wherein the charge storage film contains nitrogen, and a density of nitrogen contained in the charge storage film is larger than a density of nitrogen contained in the third film.

8. The device according to claim 2, wherein the charge storage film contains nitrogen, and a density of nitrogen contained in the charge storage film is larger than a density of nitrogen contained in the third film.

9. The device according to claim 3, wherein the charge storage film contains nitrogen, and a density of nitrogen contained in the charge storage film is larger than a density of nitrogen contained in the third film.

10. The device according to claim 4, wherein the charge storage film contains nitrogen, and a density of nitrogen contained in the charge storage film is larger than a density of nitrogen contained in the third film.

11. The device according to claim 3, wherein the cap film contains silicon nitride.

12. The device according to claim 4, wherein the cap film contains silicon nitride.

13. The device according to claim 1, wherein the charge storage film contains silicon nitride.

14. The device according to claim 1, wherein the charge storage film contains a material having a dielectric constant higher than a dielectric constant of silicon oxide.

15. The device according to claim 1, wherein the charge storage film contains aluminum oxide.

16. The device according to claim 1, wherein the charge storage film has a stacked structure of a silicon nitride film and a film containing a material having a dielectric constant higher than a dielectric constant of silicon oxide.

17. The device according to claim 1, wherein the block film contains silicon oxide.

18. The device according to claim 1, wherein the block film includes a first portion containing silicon oxide, a second portion containing silicon oxide, and a third portion provided between the first portion and the second portion and containing silicon nitride.

19. The device according to claim 1, wherein
the semiconductor layer is provided in plural,
the plurality of semiconductor layers includes:
a first semiconductor layer that is one of the plurality of semiconductor layers; and
a second semiconductor layer that is another of the plurality of semiconductor layers and is provided adjacent to the first semiconductor layer in a direction orthogonal to the stacking direction, and
the device comprises:
a connection member connecting a lower end of the first semiconductor layer and a lower end of the second semiconductor layer;
a first interconnection connected to an upper end of the first semiconductor layer; and
a second interconnection connected to an upper end of the second semiconductor layer.

20. The device according to claim 1, wherein
the semiconductor layer is provided in plural,
the plurality of semiconductor layers includes:
a first semiconductor layer that is one of the plurality of semiconductor layers; and
a second semiconductor layer that is another of the plurality of semiconductor layers and is provided adjacent to the first semiconductor layer in a direction orthogonal to the stacking direction, and
the device comprises:
a first interconnection connecting an upper end of the first semiconductor layer and an upper end of the second semiconductor layer; and
a second interconnection connecting a lower end of the first semiconductor layer and a lower end of the second semiconductor layer.
